(19) United States
(12) Patent Application Publication
(10) Pub. No.: US 2014/0001513 A1
(43) Pub. Date: Jan. 2, 2014

(54) LAYER SYSTEM OF A SILICON-BASED SUPPORT AND A HETEROSTRUCTURE APPLIED DIRECTLY ONTO THE SUPPORT

(71) Applicants: Armin Dadgar, Berlin (DE); Alois Krost, Berlin (DE)

(72) Inventors: Armin Dadgar, Berlin (DE); Alois Krost, Berlin (DE)

(73) Assignee: Otto-von-Guericke-Universität Magdeburg, Magdeburg (DE)

(21) Appl. No.: 13/824,436

(22) PCT Filed: Aug. 31, 2011
(86) PCT No.: PCT/EP11/64960

§ 371 Date: Sep. 16, 2013

(30) Foreign Application Priority Data
Sep. 16, 2010 (DE) 10 2010 040 860.3

(51) Int. Cl. H01L 29/06

(52) U.S. Cl. CPC H01L 29/0684
USPC 257/183; 257/94

(57) ABSTRACT

The invention relates to a layer system composed of a silicon-based carrier having a single-crystal surface and of a heterostructure applied directly to the single-crystal surface of the carrier. The layer system according to the invention is characterized in that the carrier comprises a silicon substrate doped with one or more dopants, wherein the doped portion extends across at least 30% of the thickness of the doped silicon substrate and a concentration of the dopants in the doped portion of the silicon substrate is predetermined such that a corrected limiting concentration GK meets the condition of formula (1):

$$GK = {\sum }_{m = i}^{n} \frac{{N}_{dot}^{i}}{1 + \frac{5 \times {10}^{22} {cm}^{- 3}}{{N}_{dot}^{i}} {e}^{- {E}_{A}^{i} / 0.095 eV}} \geq 1 \times {10}^{15} {cm}^{- 3} \qquad ( 1 )$$

wherein i represents the respective dopant in the silicon substrate, N_{dot} represents the dopant concentration in cm⁻³ and E_{A} represents an energy barrier of the dopant in eV, which energy barrier inhibits dislocation glide.

The invention relates to a layer system composed of a silicon-based carrier and a heterostructure applied directly to the carrier.

### PRIOR ART AND BACKGROUND OF THE INVENTION

Impurities in silicon substrates are mostly added intentionally in the form of dopants in order to adjust electrical conductivity. Otherwise, however, such impurities are usually undesirable and are usually removed, by means of costly methods, from the raw material or during the crystal growing process. Undesirable impurities may have negative effects on components since some of them heavily diffuse in silicon and may negatively influence the electrical properties. Depending on the respective manufacturing method, silicon contains impurities of different concentrations, e.g., usually oxygen in silicon produced according to the Czochralski process (CZ); when zone melting (float zone (FZ) is used, impurities of considerable concentrations are usually present in the end pieces of the crystal only. For example, oxygen in CZ substrates causes metallic impurities to be gettered thereto, which is undesirable in a zone near the future components, which is why one endeavors to remove said impurities from at least one near-surface zone by means of temperature treatment steps.

Some impurities, such as oxygen and nitrogen, are known to significantly block dislocation glide and thereby slightly harden the silicon, which does not considerably influence elasticity within normal load limits.

The growth of heterolayers (heterostructures) on silicon substrates is relevant to a large number of applications in the fields of microelectronics, sensor technology and optoelectronic components, whether in connection with silicon or while using silicon as a cheap and large-surface substrate for layer production, which is removed from the layer later on.

Problems that will occur during the epitaxial growth of the heterolayers can be particularly explained using the example of the growth of group-III nitrides (such as AlN, GaN, InN and the mixed systems thereof) on silicon. The growth of such group-III-nitride layers mostly takes place at temperatures above 900° C. (except for InN-containing layers), wherein a problem occurring during the growth of these materials on silicon consists in a high tensile strain occurring during cooling-down. Said high tensile strain results from the low thermal expansion coefficient of silicon and the high (in relation to the low thermal expansion coefficient of silicon) expansion coefficient of the group-III nitrides and results in cracks in the epitaxially grown layers even with layer thicknesses less than 1 μm.

One can counteract said problem by applying compressive prestress to the growing layer during the growth process. If one epitaxially grows a thick layer or at very high temperatures (which is advisable for Al-rich layers in the AlGaN system), a very high compressive strain inherently develops or, if no layers causing special compression are present, tensile strain develops in the layer on account of heteroepitaxial growth. This results in a plastic deformation of the substrate, wherein a high-purity FZ substrate of higher crystal quality deforms earlier than CZ substrates. FIG. 1 schematically shows such a substrate 100 on a heated support 104 (Part a of FIG. 1). Said substrate 100 bends due to strain so that a substrate 101 results (Part b of FIG. 1). If forces exceed a threshold value, plastic deformation occurs, which mostly starts at the hotter supported edge. Said plastic deformation is shown in Part c of FIG. 1 (see hatched portion in substrate 102). This portion usually extends across the whole substrate 103 (see schematic representation in Part d of FIG. 1). Such plastic deformation is undesirable since it is usually uncontrollable so that the growth process cannot be controlled any more. Different surface temperatures may result in compositional or structural inhomogeneities. Moreover, it is impossible to balance the thermal tensile strain occurring during cooling-down by smartly selecting compressive prestress in order to obtain an even wafer consisting of a substrate and a layer.

One possibility of reducing said problem consists in using thick substrates, which is described, inter alia, in DE 102006008929 A1. However, said last-mentioned method usually definitely fails at growth temperatures above approximately 1050° C. since the substrate has a very strong tendency toward plastic deformation at such temperatures. On the other hand, said method fails with very thick applied layers since the silicon substrate thickness would have to increase to values that would be difficult to handle both in the manufacturing process and in subsequent processes.

The object of the invention is to find a solution to the problem of plastic deformation in heteroepitaxy or of the deposition of strained layers at high temperatures, whether for very thick strained layers or in order to be able to use substrates having normal thicknesses according to the SEMI standard (or no excessively thick substrates, which would cause a large number of problems during subsequent processing.)

### Inventive Solution

The layer system according to the invention composed of a silicon-based carrier having a single-crystal surface and of a heterostructure applied directly to the single-crystal surface of the carrier is characterized in that the carrier comprises a silicon substrate doped with one or more dopants, wherein the doped portion extends across at least 30% of the thickness of the doped silicon substrate and a concentration of the dopants in the doped portion of the silicon substrate is predetermined such that a corrected limiting concentration GK meets the condition of formula (1):

$$GK = {\sum }_{m = i}^{n} \frac{{N}_{dot}^{i}}{1 + \frac{5 \times {10}^{22} {cm}^{- 3}}{{N}_{dot}^{i}} {e}^{- {E}_{A}^{i} / 0.095 eV}} \geq 1 \times {10}^{15} {cm}^{- 3} \qquad ( 1 )$$

wherein i represents the respective dopant in the silicon substrate, N_{dot} represents the dopant concentration in cm⁻³ and E_{A} represents an energy barrier of the dopant in eV, which energy barrier inhibits dislocation glide.

The invention is based on the discovery that the plastic deformation of the silicon substrate can be inhibited by providing the silicon with dopants, wherein the necessary concentration depends on the strength of the bond between the dopant and the dislocation, which is taken into consideration by the above formula (1). The effects of several dopants may be added up in order to reach the limiting concentration GK. The dopant may be an element or a compound. However, the doped portion of the silicon substrate preferably contains only one or two dopants. Furthermore, the dopant is preferably an element of the group comprising oxygen, nitrogen, carbon, boron, arsenic, phosphorus and antimony or a compound of said elements among themselves or a compound of oxygen or nitrogen with a metal, preferably with aluminum or a transition metal.

The minimum thickness to be doped in the substrate is 30%, preferably 50%. Ideally, however, the substrate is doped as thoroughly as possible. Depending on the respective dopant, modulation doping during substrate or single-crystal production might also be useful from a procedural aspect. However, said modulation doping should meet the above-mentioned condition for at least 30% of the future substrate thickness. As discussed below, the bonding of two different substrate qualities is also possible, from which a partial doping follows automatically.

According to a preferred embodiment, the doped silicon substrate is doped with carbon with a concentration N_{dot}≧1×10¹⁹ cm⁻³. Carbon as an isovalent dopant in silicon is highly suitable for inhibiting plastic deformation provided that the carbon exceeds the above-mentioned concentration, wherein the particular processes have not been completely clarified, yet. One phenomenon that can be frequently observed in carbon is the formation of high-carbon precipitates that harden the crystal.

In addition or alternatively, the doped silicon substrate is doped with nitrogen (E_{A}˜1.7-2.4 eV) with a concentration N_{dot}≧1×10¹⁵ cm⁻³ or with oxygen (E_{A}˜0.57-0.74 eV) with a concentration N_{dot}≧1×10¹⁸ cm⁻³ (see S. M. Hu, Appl. Phys. Lett. 31, 53 (1977) and A. Giannattasio et al., Physica B 340-342, 996 (2003)).

The energy barriers mentioned herein that inhibit dislocation glide correspond to the binding energies of the materials to dislocations that are mentioned in the literature. The large spread clearly shows that determination is not easy, which is partly due to the reaction with other materials present in the crystal but also due to the fact that the materials are bound to the dislocation differently as well as due to the additional influence of diffusion, which is one of the decisive factors with respect to providing the dislocation with the dopant. Rough approximate values for the suitability of a dopant can be estimated on the basis of the known binding enthalpies or binding energies of silicon with the respective materials, which are mostly significantly higher than the ones mentioned above. For example, the value for the Si—O bond amounts to several eV. Since the situation in the crystal is significantly more complex, it is advisable to perform determination experimentally.

Various methods are suitable therefor. Only some of these methods will be mentioned in the following:

A nanoimpression technique is described in Christopher A. Schuh, Materials Today 9, 32 (2006), by means of which it is possible to determine, depending on the temperature and knowing the dopant concentration/s as against undoped material, the activation energy from the amount of force at which plastic deformation begins. In addition to the determination of the dopant concentration (e.g., by means of secondary-ion mass spectroscopy (SIMS)), it is necessary to know the formed dislocation line density in order to be able to determine an activation energy, which can be determined sufficiently accurately by means of transmission electron microscopy methods or by means of defect etching. Other suitable methods are temperature-dependent bending experiments, in which the substrate material is bent and the bending force is recorded. The beginning of plastic deformation is usually characterized by a decreasing force during bending. Thus, the activation energy can be determined provided that the dopant concentration/s is/are known. Determination is also possible by means of methods that are based on the temperature-dependent measurement of the force-bending characteristics. It is also possible to use the substrates in the MOVPE process: If a tensile-strained or compressively strained layer is epitaxially grown on the substrate, it is possible to determine, by means of in-situ curvature measurement or combined surface temperature measurement, from what pressure and at what temperature plastic deformation occurs. Ideally, a tensile-strained layer is used since the temperature is measured, when such a layer is used, at the point of support (where temperature is at its maximum) so that the result is least distorted. Thus, provided that the dopant concentration is known and on the basis of the dislocation line density determined later on, the activation energy can be determined by varying the growth temperature, which can be easily varied within a range of about 100° C. in a large number of methods, wherein it is possible to count (using a Nomarski microscope) the dislocations during the growth of group-III nitrides if the density of dislocations is moderate. It is essential to interrupt growth at the beginning of deformation in order not to cause a large increase in dislocation line density, which increase would distort the measuring result. A high-purity FZ substrate is an ideally suitable reference. Depending on the respective dopant, a substrate grown according to the Czochralski process might also be useful. CZ material usually contains more oxygen than FZ substrates, which has an effect if the substrate is doped with additional dopants (e.g., with nitrogen or boron), also because materials can react with each other.

Other methods that use ultrasound are also described in the literature (see, e. g., V. I. Ivanov et al. Phys. Stat. Sol. a 65, 335 (1981)).

Dopant concentrations of boron, phosphorus, arsenic and antimony and other elements that have very low activation energies inhibiting dislocation glide also have, from concentrations of approximately 10²⁰ cm⁻³, an inventively usable effect that inhibits dislocation glide. The question whether this is due to cluster or precipitate formation or not has not been adequately answered, yet. However, an effect at high dopant concentrations can be expected even with low energy barriers, which can be explained by the fact that the silicon bonds present at the dislocation line are provided with a large number of dopants, wherein the mostly high diffusivity of the materials at high temperatures plays a role, which diffusivity is mostly high due to the low energy barrier and mostly causes an accumulation of dislocations.

Preferably, the limiting concentration GK (minimum concentration) following from formula (1) is ≧5×10¹⁵, in particular 1×10¹⁶. The mentioned limits do cause a noticeable hardening of the crystal but are sufficient for a large number of processes in which heavily strained layers are produced. For example, when a 3 μm GaN layer is grown on silicon by means of MOVPE at a temperature of approximately 1050° C., thermal strain energy amounts to approximately 1.5-2 GPa. In order to compensate for said energy, a corresponding compressive strain must be developed during growth. Said compressive strain is above the limit for plastic deformation of high-purity silicon. In commercially available CZ crystals, on account of the residual impurities in the form of oxygen or nitrogen and the impurities in the form of an n-dopant or a p-dopant, such a thickness can be realized, in most cases, without the occurrence of plastic deformation provided that a substrate having a thickness of >500 μm is used. Even here, however, thicker layers quickly come up against limiting factors that make the inventive hardening of the crystal inevitable since substrates must otherwise reach thicknesses on the order of 2 mm, which makes little sense from a technological aspect since the thinning process required for processing would be costly and a large amount of material would have to be used.

With FZ substrates, the above-mentioned minimum concentrations already cause a considerable inhibition of plastic deformation, said inhibition being sufficient for the layer structure, wherein it is not necessary to prevent any formation of dislocation (as desired in U.S. Pat. No. 6,258,695 B1, for example) but only that amount of dislocation glide which results in measurable plastic deformation. Said measurable plastic deformation is easily discernible in, e.g., Nomarski or differential interference contrast microscopy images of GaN on (111) silicon layers (crossed pattern, shown in FIG. 4 by way of example) and in in-situ curvature measurements (sudden buckling/sharp increase in curvature values, which cannot be explained by the applied stress or the layer structure).

In FIG. 4, the white subsidiary lines mark the deformation lines, which run only in two directions in this example. Here, the third direction is not yet distinct enough so that it is not clearly visible in the image. Slight deformations, i.e., dislocation formation that does not result in such a distinct behavior, are usually not relevant to the inventive layer system since slight deviations from the ideal curvature, which are accompanied by slight plastic deformation and are not detectable by, e.g., in-situ curvature measurement, do not have any significant effect on future component behavior.

The crystal may be doped with the dopants in various ways, e.g., by means of diffusion or implantation. On account of their usually high purity and perfection, FZ substrates have a tendency toward plastically deforming much earlier than CZ substrates. The obtainable layer thickness that can be obtained on FZ substrates without plastic deformation often amounts to only about half of that of CZ substrates, wherein nitrogen is particularly advantageous since it improves the compensation properties of high-resistivity FZ substrates of the type preferred in high-frequency applications.

Generally, adding nitrogen to silicon is particularly advantageous since dislocations are more stable than in the case of the addition of oxygen. On account of its lower energy barrier, oxygen loses part of its inhibitory effect on dislocation motion from a temperature of 800° C. already. Nitrogen loses part of its inhibitory effect from a temperature of 1200° C. only, which makes much higher process temperatures possible. The behavior of carbon is similar to that of nitrogen. On account of the different incorporation behavior of carbon, however, higher carbon concentrations are necessary in order to achieve a corresponding effect.

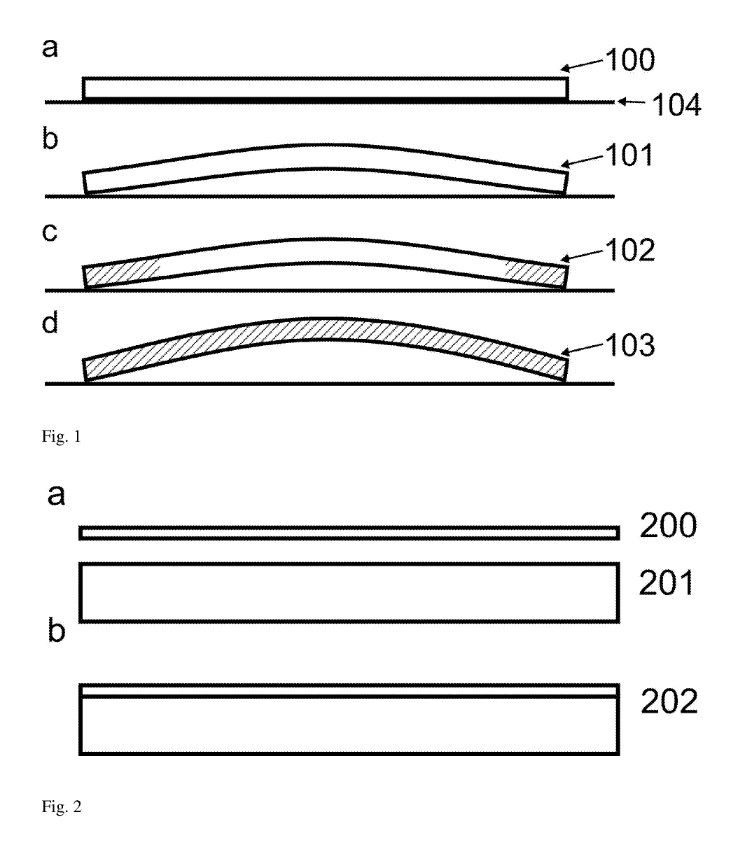

According to a further preferred embodiment, the carrier comprises an undoped silicon substrate, to which the heterostructure is applied directly and which is connected to the doped silicon substrate directly or via an intermediate layer, i.e., this approach provides the production of a carrier by bonding two silicon-containing substrates. One substrate is very heavily doped with at least one of the dopants and the other substrate is, e.g., highly pure and highly resistive and provides the single-crystal surface on which the heterostructure is grown epitaxially. This embodiment is schematically shown in FIG. 2, where a high-quality substrate 200 that is made of pure silicon and mostly very thin is connected to a very heavily doped silicon-based substrate 201 so that the carrier 202 results (Part b of FIG. 2). Thus, by bonding, properties of a high-quality substrate can be combined for the epitaxy with a high-strength substrate, wherein the doped substrate, which is actually of inferior quality, may also include heavy crystal defects, which often occur in the form of precipitates at very high dopant concentrations.

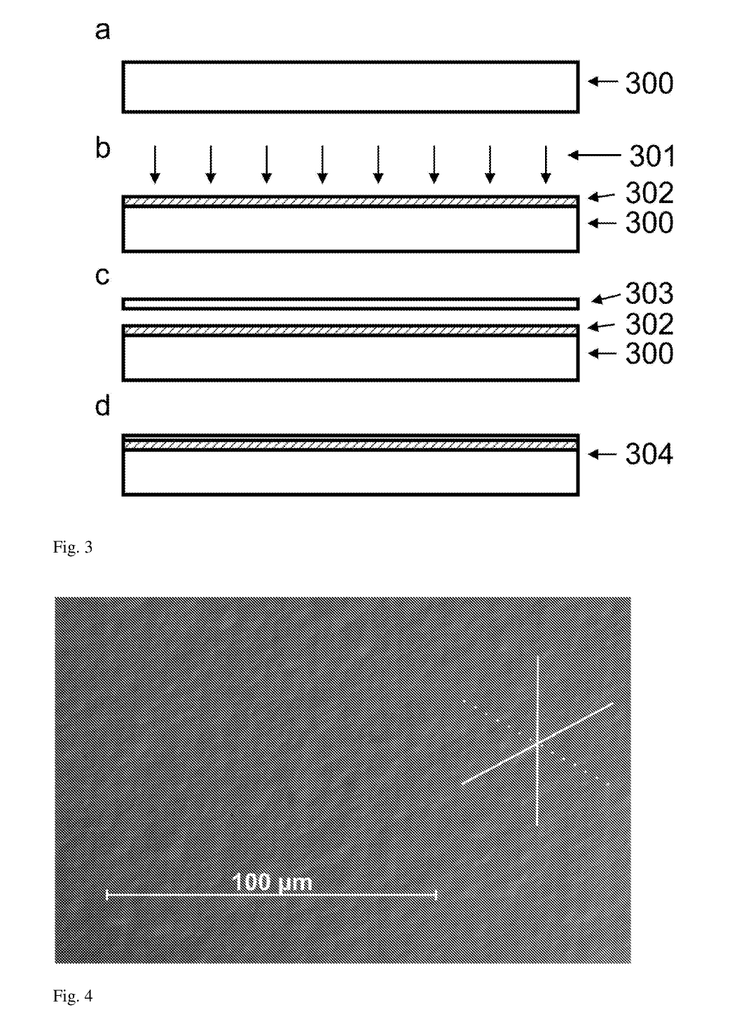

Such a bonding technique may be direct Si—Si bonding or may be performed by means of an intermediate adhesion promoter layer, e.g., on the basis of oxides, nitrides, oxinitrides, carbides of silicon or other metals, wherein this adhesive bond must also be stable at the process temperatures of group-III-nitride growth. Such a bonding process by means of an adhesion promoter layer is shown in FIG. 3. Part a of FIG. 3 shows the doped substrate 300, which is provided with an adhesion promoter layer 302 (see Part b of FIG. 3), which may be performed by means of, e.g., a sputtering, vapor deposition, spraying or imprinting process 301. After that, the adhesion promoter layer 302 is provided with a high-quality covering substrate 303 made of silicon (see Part c of FIG. 3). Said covering substrate 303 is then available, as a carrier 304 (see Part d of FIG. 3) having a high-quality surface and being highly resistant to plastic deformation, for the process of applying the heterostructure. The combination of high-resistivity FZ substrates and heavily doped CZ substrates is particularly promising with respect to high-frequency applications, which require low parasitic capacitances and thus high-resistivity buffers and substrates.

A high-quality surface region can also develop when the substrate is tempered in an inert atmosphere or in a vacuum where the dopants diffuse, at a sufficient temperature, out of a surface region having a thickness from several 100 nm to several micrometers. Depending on the respective dopant, a reactive atmosphere (aside from the inert atmosphere or a vacuum) can also promote outward diffusion by surface reactions.

Layers or layer structures are usually component layer structures of the type that is, e.g., mostly required for group-III-nitride light emitting diodes or transistors where it turned out that the best approach to achieving an efficient light decoupling of light emitting diodes is the thin-film approach, i.e., a layer having a thickness of 4 to 5 micrometers is grown on the silicon substrate and then transferred to a new highly reflective carrier, wherein the original substrate is removed later on. Here, the thickness of the layer is necessary for the transfer process itself and in order to be able to place a rough light decoupling layer. If no thin-film process is performed, light decoupling is improved if thick layers are used since brightness increases in this case on account of less lossy reflections of laterally emitted light.

With transistors, thick layers are important particularly for high-voltage components since the breakdown field strength essentially depends on the thickness of the layer aside from material quality and contact clearance. With high-frequency transistors, the influence of the silicon substrate, which is still fairly conductive in most cases and acts as an absorbing RC module, decreases with increasing layer thickness. Other components that require a low influence of the substrate on component properties or thick layers on account of their stability (e.g., MEMS), are also ideally suitable for being grown on the inventive substrates since this can be achieved for thick layers in this manner only or by using very thick substrates that are difficult to process. Therefore, the layer system is preferably a component layer structure of a high-frequency transistor or of a light emitting diode.

The term “heterostructure” does not only refer to the group-III nitrides mentioned by way of example but generally refers to strained layers made of other materials (such as silicon) that are deposited on silicon substrates at temperatures above the above-mentioned ones or are processed thermally. Processing at high temperatures may already result in plastic deformation in strained systems if said systems were produced at lower temperatures, for example, which can be prevented by using the inventive layer systems.

1. A layer system composed of a silicon-based carrier having a single-crystal surface and of a heterostructure applied directly to the single-crystal surface of the carrier,
characterized in that
the carrier comprises a silicon substrate doped with one or more dopants, wherein the doped portion extends across at least 30% of the thickness of the doped silicon substrate and a concentration of the dopants in the doped portion of the silicon substrate is predetermined such that a corrected limiting concentration GK meets the condition of formula (1):
$$GK = {\sum }_{m = i}^{n} \frac{{N}_{dot}^{i}}{1 + \frac{5 \times {10}^{22} {cm}^{- 3}}{{N}_{dot}^{i}} {e}^{- {E}_{A}^{i} / 0.095 eV}} \geq 1 \times {10}^{15} {cm}^{- 3} \qquad ( 1 )$$
wherein i represents the respective dopant in the silicon substrate, N_{dot} represents the dopant concentration in cm⁻³ and E_{A} represents an energy barrier of the dopant in eV, which energy barrier inhibits dislocation glide.

2. The layer system according to claim 1, in which the doped silicon substrate has one or two dopants.

3. The layer system according to claim 1, in which the doped silicon substrate is doped with oxygen with a concentration N_{dot}≧1×10¹⁸ cm⁻³.

4. The layer system according to claim 1, in which the doped silicon substrate is doped with nitrogen with a concentration N_{dot}≧1×10¹⁵ cm⁻³.

5. The layer system according to claim 1, in which the doped silicon substrate is doped with carbon with a concentration N_{dot}≧1×10¹⁹ cm⁻³.

6. The layer system according to claim 1, in which the carrier comprises an undoped silicon substrate, to which the heterostructure is applied directly and which is connected to the doped silicon substrate directly or via an intermediate layer.

7. The layer system according to claim 1, in which the corrected limiting concentration GK is ≧5×10¹⁵ cm⁻³.

8. The layer system according to claim 1, in which the layer system is a component layer structure of a high-frequency transistor or of a light emitting diode.

9. The layer system according to claim 2, in which the doped silicon substrate is doped with oxygen with a concentration N_{dot}≧1×10¹⁸ cm⁻³.

10. The layer system according to claim 2, in which the doped silicon substrate is doped with nitrogen with a concentration N_{dot}≧1×10¹⁵ cm⁻³.

11. The layer system according to claim 3, in which the doped silicon substrate is doped with nitrogen with a concentration N_{dot}≧1×10¹⁵ cm⁻³.

12. The layer system according to claim 2, in which the doped silicon substrate is doped with carbon with a concentration N_{dot}≧1×10¹⁹ cm⁻³.

13. The layer system according to claim 3, in which the doped silicon substrate is doped with carbon with a concentration N_{dot}≧1×10¹⁹ cm⁻³.

14. The layer system according to claim 4, in which the doped silicon substrate is doped with carbon with a concentration N_{dot}≧1×10¹⁹ cm⁻³.

15. The layer system according to claim 2, in which the carrier comprises an undoped silicon substrate, to which the heterostructure is applied directly and which is connected to the doped silicon substrate directly or via an intermediate layer.

16. The layer system according to claim 3, in which the carrier comprises an undoped silicon substrate, to which the heterostructure is applied directly and which is connected to the doped silicon substrate directly or via an intermediate layer.

17. The layer system according to claim 4, in which the carrier comprises an undoped silicon substrate, to which the heterostructure is applied directly and which is connected to the doped silicon substrate directly or via an intermediate layer.

18. The layer system according to claim 5, in which the carrier comprises an undoped silicon substrate, to which the heterostructure is applied directly and which is connected to the doped silicon substrate directly or via an intermediate layer.

19. The layer system according to claim 2, in which the corrected limiting concentration GK is ≧5×10¹⁵ cm⁻³.

20. The layer system according to claim 3, in which the corrected limiting concentration GK is ≧5×10¹⁵ cm⁻³.

21. The layer system according to claim 4, in which the corrected limiting concentration GK is ≧5×10¹⁵ cm⁻³.

22. The layer system according to claim 5, in which the corrected limiting concentration GK is ≧5×10¹⁵ cm⁻³.

23. The layer system according to claim 6, in which the corrected limiting concentration GK is ≧5×10¹⁵ cm⁻³.

24. The layer system according to claim 2, in which the layer system is a component layer structure of a high-frequency transistor or of a light emitting diode.

25. The layer system according to claim 3, in which the layer system is a component layer structure of a high-frequency transistor or of a light emitting diode.

26. The layer system according to claim 4, in which the layer system is a component layer structure of a high-frequency transistor or of a light emitting diode.

27. The layer system according to claim 5, in which the layer system is a component layer structure of a high-frequency transistor or of a light emitting diode.

28. The layer system according to claim 6, in which the layer system is a component layer structure of a high-frequency transistor or of a light emitting diode.

29. The layer system according to claim 7, in which the layer system is a component layer structure of a high-frequency transistor or of a light emitting diode.
